(19) United States
(12) Patent Application Publication
(10) Pub. No.: US 2020/0105626 A1
(43) Pub. Date: Apr. 2, 2020

(54) ARCING TEST VEHICLE AND METHOD OF USE THEREOF

(71) Applicant: APPLIED MATERIALS, INC., Santa Clara, CA (US)

(72) Inventors: MINGDONG LI, SANTA CLARA, CA (US); LEI ZHOU, SANTA CLARA, CA (US); CHAO DU, SUNNYVALE, CA (US); YONG CAO, SAN JOSE, CA (US); CHEN GONG, SUNNYVALE, CA (US); BO XIE, SAN JOSE, CA (US); YONGMEI CHEN, SAN JOSE, CA (US); SONG-MOON SUH, SAN JOSE, CA (US); RONGJUN WANG, DUBLIN, CA (US); XIANMIN TANG, SAN JOSE, CA (US)

(21) Appl. No.: 16/267,857

(22) Filed: Feb. 5, 2019

Related U.S. Application Data
(60) Provisional application No. 62/737,432, filed on Sep. 27, 2018.

(51) Int. Cl. H01L 21/66; H01L 21/02; H01L 21/3065

(52) U.S. Cl. CPC H01L 22/14; H01L 21/3065; H01L 21/02236; H01L 21/02126

(57) ABSTRACT

Methods and apparatus for simulating arcing that can occur during substrate fabrication is provided. In some embodiments, the method includes: loading a bare silicon substrate that has been pretreated with at least one of polybutylene terephthalate (PBT) or a film into a testing environment, performing a physical vapor deposition (PVD) process on the bare silicon substrate, and determining arcing occurrences on the bare silicon substrate caused during the PVD process.

### CROSS-REFERENCE TO RELATED APPLICATION(S)

This application claims priority to U.S. Provisional Application Ser. No. 62/737,432, which was filed on Sep. 27, 2018, the entire contents of which is incorporated herein by reference.

### FIELD

The disclosure generally relates to thin film manufacturing techniques, and more particularly, to an arcing test vehicle and method of use thereof suitable, for example, for simulating arcing, which can occur during substrate fabrication, using one or more test vehicles.

### BACKGROUND

Arcing, while infrequent, can occur during one or more processes of substrate fabrication (e.g., wafer fabrication). For example, during PVD, contaminants (which can be present on the substrate (e.g., oxidation), within a structure of a target (inclusion), or in the PVD chamber (e.g., vacuum grease)) can interact with the PVD process and/or the hardware associated therewith and cause arcing.

One or more pre-cleaning processes (e.g., wafer scrub or other pre-cleaning process) can be used prior to introducing the wafer into the PVD chamber to remove the contaminants and reduce or eliminate the occurrence of arcing. Another approach is to eliminate/reduce arcing during wafer fabrication, but because the frequency at which arcing occurs during substrate fabrication is relatively low, arcing is difficult to analyze to define a successful pre-cleaning process, a successful fabrication condition, or a successful combined bundle approach.

### SUMMARY

Embodiments of arcing test vehicles and methods of use thereof are provided herein. In accordance with an aspect of the disclosure, there is provided a method for simulating arcing that can occur during substrate fabrication. The method includes loading a bare silicon substrate that has been pretreated with at least one of polybutylene terephthalate (PBT) or a film into a testing environment, performing a physical vapor deposition (PVD) process on the bare silicon substrate, and determining arcing occurrences on the bare silicon substrate caused during the PVD process.

In accordance with an aspect of the disclosure, there is provided a nontransitory computer readable storage medium having stored thereon a plurality of instructions that when executed perform a method for simulating arcing which can occur during wafer fabrication. The method includes loading a bare silicon substrate that has been pretreated with at least one of polybutylene terephthalate (PBT) or a film into a testing environment, performing a physical vapor deposition (PVD) process on the bare silicon substrate, and determining arcing occurrences on the bare silicon substrate caused during the PVD process.

In accordance with an aspect of the disclosure, there is provided a system for simulating arcing that can occur during substrate fabrication. The system includes a bare silicon substrate that has been pretreated with at least one of polybutylene terephthalate (PBT) or a film, a testing environment for performing a physical vapor deposition (PVD) process on the bare silicon substrate, and at least one device used for determining arcing occurrences on the bare silicon substrate caused during the PVD process.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a diagram of a PVD chamber having an arcing test vehicle disposed therein, in accordance with at least some embodiments of the disclosure;

FIGS. 2A and 2B are schematic diagrams of an arcing test vehicle, in accordance with at least some embodiments of the disclosure; and

FIG. 3 is a flowchart of a method for simulating arcing during substrate fabrication, in accordance with at least some embodiments of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the disclosure will be described herein below with reference to the accompanying drawings. However, the embodiments of the disclosure are not limited to the specific embodiments and should be construed as including all modifications, changes, equivalent devices and methods, and/or alternative embodiments of the disclosure. In the description of the drawings, similar reference numerals are used for similar elements

Methods and apparatuses for simulating arcing using one or more test vehicles are now herein described.

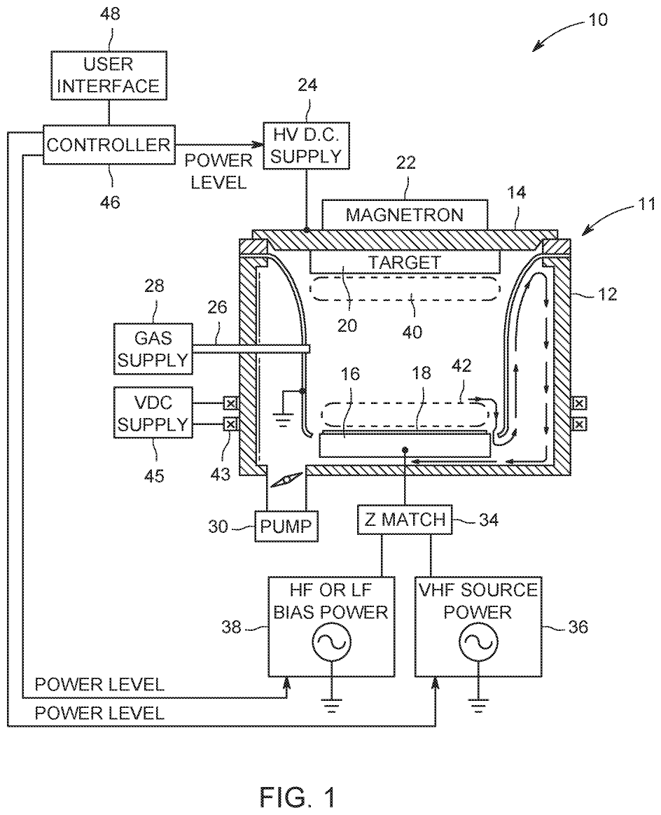

FIG. 1 is a diagram of a system 10 including a PVD chamber 11, in accordance with an embodiment of the disclosure. The PVD chamber 11 is defined by a cylindrical sidewall 12, a disk-shaped ceiling 14, and a substrate support 16 for supporting a substrate 18 (e.g., a wafer) to be processed. The substrate 18 can made from silicon (Si), Si thermal oxide, an SiO coated Si substrate 18, or other suitable material. In the illustrated embodiment, the wafer is a Si substrate (e.g., a “dummy” or “blanket” substrate, or a dummy wafer.

A target 20 of metal (e.g., titanium (Ti), tantalum (Ta), Ti nitride (TiN), or other suitable material to be deposited on the substrate 18 is mounted on the ceiling 14. A magnetron 22 overlies the target 20 on an external side of the ceiling 14, and a high voltage D.C. source 24 is coupled to the target 20. A process gas injector 26 furnishes process gas (top flow gas, backflow gas, etc.) from a supply 28 into the interior of the chamber, and a vacuum pump 30 maintains a desired sub-atmospheric pressure in the vacuum chamber.

An impedance match network 34 connects to a VHF plasma source power generator 36 and to an HF or LF bias power generator 38. The high voltage D.C. source 24 maintains an upper plasma 40 near the target 20, and the VHF plasma source power generator 24 maintains a lower plasma 42 at or near the surface of the substrate 18. The two plasmas 40, 42 may be maintained simultaneously or may be produced at different times. Plasma uniformity, particularly uniformity of the plasma 42 nearest the wafer, is controlled by an electromagnetic coil 43 wrapped around the cylindrical sidewall 12 and supplied with D.C. current by a current source controller 45.

A process controller 46 (or processor) controls the overall operation of the PVD chamber 11. For example, the process controller 46 controls the power level of the target high voltage D.C. source 24, the power level of the VHF plasma source power generator 36 and the power level of the HF or LF bias power generator 38. The process controller 46 may be controlled by a user through a user interface 48, allowing the user to program the process controller 46 to have the PVD chamber 11 automatically transition between one or more operating modes, e.g., a test/or simulation mode, a conformal mode, a non-conformal mode, and/or a punch through re-sputter mode. The processor controller 46 may also control the electromagnet current source controller 45, so that in any of the modes of operation, a current level can be optimized for a more uniform radial distribution of plasma ion density distribution.

The PVD chamber 11, under the control of the process controller 46, is used as a testing environment for simulating arcing that, as noted above, can occur when PVD is being performed on a substrate, such as a wafer. More particularly, the inventors have discovered that when a substrate is pretreated (e.g., prior to PVD) in accordance with the present disclosure, the pretreated substrate can be used as an arcing test vehicle for a PVD process, such as for example, a titanium nitride (TiN) PVD process.

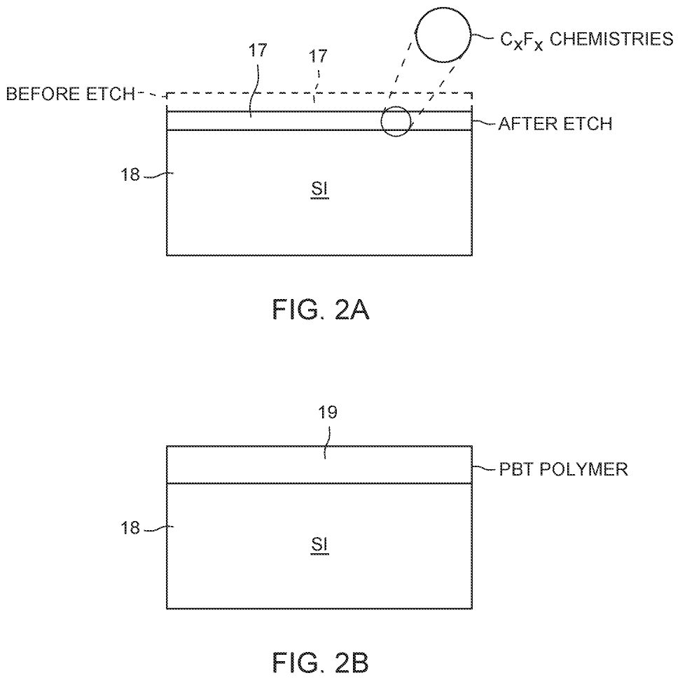

FIGS. 2A and 2B are diagrams of the substrate 18, in accordance with an embodiment of the disclosure. In FIG. 2A, the substrate 18 is pretreated by depositing, using one or more known deposition processes, a low k film 17 on the substrate 18, which, as noted above, is an Si substrate (the low k film 17 is shown in phantom prior to etching). For example, the substrate 18 can be exposed to one or more volatile precursors, which react and/or decompose on the substrate 18 surface to produce the desired deposit, such as to form a silicon oxycarbide (SiOC) low k film layer. The deposition of the low k film onto the substrate 18 includes a 1.05 kA ultra violet curing process. For example, an ultra violet (UV) curing process can be used to initiate a photochemical reaction that generates a crosslinked Si—O network of low k materials. The low k film 17 can be deposited on the entire top layer of the substrate 18, or a portion thereof. After the low k film is deposited on the substrate 18, one or more known etching processes and/or tools can be used to etch the low k film 17. For example, a reactive ion etch (RIE) conductor etch chamber that is configured to perform an RIE etch process, e.g., a blanket low k film etch process, can be used to etch the low k film 17. A significant amount of the low k film can be etched off the substrate 18, but a relatively small amount can be left on (e.g., the low k film is not fully etched off the substrate). Although, some of the low k film 17 can be etched off to expose the substrate 18, e.g., if testing environments dictate. One or more post etch treatments can also be used after the RIE etch process. For example, post etch byproduct, such as, CxFx chemistries, that remains on the substrate 18 surface can be used to enhance arching occurrences of the substrate 18 during downstream PVD deposition.

In FIG. 2B, the substrate 18 is pretreated by spraying the entire top layer thereof with PBT polymer powder/particle 19. The powder/particle can be sprayed manually in one or more controlled manners, e.g., by hand, or other suitable device.

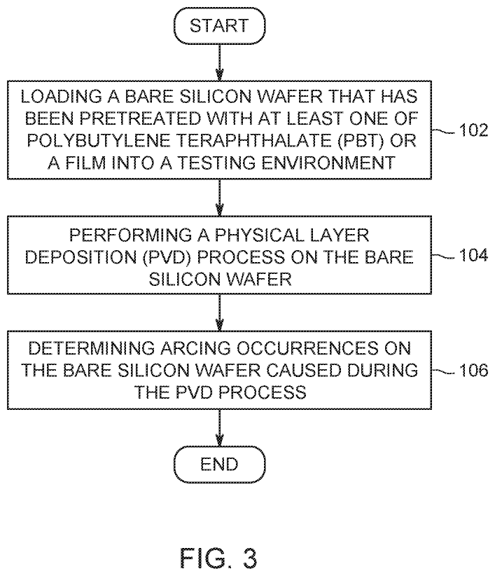

FIG. 3 is a flowchart of a method for simulating arcing which can occur during substrate fabrication, in accordance with an embodiment of the disclosure. For illustrative purposes, the method is herein described with reference to the substrate 18 having been treated with the low k film 17 of FIG. 2A.

The substrate 18 is loaded into the PVD chamber 11 at 302. PVD is then performed on the substrate 18 at 304. Thereafter, an amount (or a number) of arcing occurrences is determined at 306. The number of arcing occurrences can be determined using one or more suitable methods. For example, a CGA, an ADC, an oscilloscope or other suitable device can be used to capture an arcing occurrence under the control of the process controller 46.

The above process was repeated for fifteen substrates 18, to ensure that a large enough sample size was obtained and the validity of the simulation. More particularly, PVD was performed on a first set of five substrates 18. After PVD was performed on the first set of substrates 18, the arcing occurrences were counted for each of the first set of five substrates 18 with the following results. A first substrate 18 had twenty-two (22) arcing occurrences; a second substrate 18 had twenty (20) arcing occurrences; a third substrate 18 had twenty-three (23) arcing occurrences; a fourth substrate 18 had seventeen (17) arcing occurrences; and a substrate 18 had nineteen (19) arcing occurrences.

After the arcing occurrences for each of the first set of substrates 18 were counted, one or more parameters of the PVD process were adjusted, and PVD was performed on a second set of ten substrates 18. The one or more parameters of the PVD process that can be adjusted can include, but are not limited to a) DC power level provided to the target 20; b) one of a substrate temperature (e.g., substrate 18 temperature) or the substrate support 16 temperature set point; c) AC bias power level provided to substrate support 16; d) the PVD chamber 11 pressure; e) composition, pressure, and/or flow rate of backside gas (if used); f) composition, pressure, and/or flow rate of top gas injection (if used); g) Ti ignition (or Ti pre-deposition); or h) whether or not to degas the substrate 18 (e.g., wafer) prior to performing PVD.

In one particular embodiment, under the control of the process controller 46 the DC power was adjusted to 18 kW, the temperature of the second set of substrates 18 was adjusted to 350° C., the AC bias was adjusted to 38 W, the PVD chamber 11 pressure was adjusted to 210 mTorr, the flow rate of the backside gas was adjusted to 1 sccm, top gas injection was used, Ti ignition was used, and the second set of substrates 18 were degassed at 400° C.

After the above adjustments were made, PVD was performed on the second set of substrates 18, and the number of arcing occurrences were counted for each substrate of the second set of substrates 18. None of the substrates 18 of the second set of substrates 18 had an arcing occurrence; similar results were obtained for the substrate 18 of FIG. 2B.

The information obtained using the substrates 18 of FIGS. 2A and 2B as an arcing test vehicle allows a user to determine optimal settings for the PVD chamber 11 prior to performing PVD on a substrate (e.g., a wafer), which, in turn, can help reduce or eliminate arcing occurrences during PVD TiN on a substrate, for example, by optimizing processing conditions using the test vehicle and methods disclosed herein. In addition, because the substrates 18 are low cost (e.g., bare Si) “dummy substrates,” the costs associated with using the substrate 18—having the above described pretreatment processes performed thereto—during the above described arcing simulations is relatively low when compared to using operational/production substrates, e.g., substrates/wafers that have been processed to include one or more layers, circuits, etc.

Furthermore, the information obtained using the substrate 18 of FIGS. 2A and 2B can facilitate in the development (redesign) of new and improved substrates (wafers), which do not have high arcing tendencies. For example, manufacturers can redesign, for example, the various layers, types of materials, etc., of substrates which have specific patterns that are known to have relatively high arcing occurrences during a PVD TiN process.

While the foregoing has been shown and described with reference to certain embodiments thereof, various changes in form and details may be made therein without departing from the scope of the disclosure. Therefore, the scope of the disclosure should not be defined as being limited to the embodiments.

What is claimed is:

1. A method for simulating arcing that can occur during substrate fabrication, the method comprising:
loading a bare silicon substrate that has been pretreated with at least one of polybutylene terephthalate (PBT) or a film into a testing environment;
performing a physical vapor deposition (PVD) process on the bare silicon substrate; and
determining arcing occurrences on the bare silicon substrate caused during the PVD process.

2. The method of claim 1, wherein the PBT is sprayed on the bare silicon substrate, and the film is a low k material.

3. The method of claim 1, wherein pretreating the bare silicon substrate comprises etching the film.

4. The method of claim 1, wherein the testing environment is a PVD chamber.

5. The method of claim 1, wherein determining arcing occurrences comprises counting a number of arcing occurrences on the on the bare silicon substrate during the PVD process.

6. The method of claim 5, further comprising:
removing the bare silicon substrate from the testing environment;
adjusting at least one parameter associated with the PVD process;
loading another bare silicon substrate that has been pretreated with at least one of PBT or a film into the testing environment;
performing a PVD process on the another bare silicon substrate; and
counting a number of arcing occurrences on the another bare silicon substrate caused during the PVD process.

7. The method of claim 6, wherein the at least one parameter associated with PVD is at least one of:
a) DC power level provided to a target;
b) one of a substrate temperature or a substrate support temperature set point;
c) AC bias power level provided to the substrate support;
d) PVD chamber pressure;
e) one of a composition, pressure, or flow rate of backside gas;
f) one of a composition, pressure, or flow rate of top gas injection;
g) titanium (Ti) ignition; or
h) whether or not to use a degassing process, and if so, a temperature used during the degassing process.

8. A nontransitory computer readable storage medium having stored thereon a plurality of instructions that when executed perform a method for simulating arcing that can occur during substrate fabrication, the method comprising:
loading a bare silicon substrate that has been pretreated with at least one of polybutylene terephthalate (PBT) or a film into a testing environment;
performing a physical vapor deposition (PVD) process on the bare silicon substrate; and
determining arcing occurrences on the bare silicon substrate caused during the PVD process.

9. The nontransitory computer readable storage medium of claim 8, wherein the PBT is sprayed on the bare silicon substrate, and the film is a low k material.

10. The nontransitory computer readable storage medium of claim 8, wherein pretreating the bare silicon substrate comprises etching the film.

11. The nontransitory computer readable storage medium of claim 8, wherein the testing environment is a PVD chamber.

12. The nontransitory computer readable storage medium of claim 8, wherein determining arcing occurrences comprises counting a number of arcing occurrences on the on the bare silicon substrate during the PVD process.

13. The nontransitory computer readable storage medium of claim 12, further comprising:
removing the bare silicon substrate from the testing environment;
adjusting at least one parameter associated with the PVD process;
loading another bare silicon substrate that has been pretreated with at least one of PBT or a film into the testing environment;
performing a PVD process on the another bare silicon substrate; and
counting a number of arcing occurrences on the another bare silicon substrate caused during the PVD process.

14. The nontransitory computer readable storage medium of claim 13, wherein the at least one parameter associated with PVD is at least one of:
a) DC power level provided to a target;
b) one of a substrate temperature or a substrate support temperature set point;
c) AC bias power level provided to the substrate support;
d) PVD chamber pressure;
e) one of a composition, pressure, or flow rate of backside gas;
f) one of a composition, pressure, or flow rate of top gas injection;
g) titanium (Ti) ignition; or
h) whether or not to use a degassing process, and if so, a temperature used during the degassing process.

15. A system for simulating arcing that can occur during substrate fabrication, the system comprising:
a bare silicon substrate that has been pretreated with at least one of polybutylene terephthalate (PBT) or a film;
a testing environment for performing a physical vapor deposition (PVD) process on the bare silicon substrate; and
at least one device used for determining arcing occurrences on the bare silicon substrate caused during the PVD process.

16. The system of claim 15, wherein the PBT is sprayed on the bare silicon substrate, and the film is a low k material.

17. The system of claim 15, wherein the bare silicon substrate is pretreated by etching the film, and wherein the testing environment is a PVD chamber.

18. The system of claim 15, wherein the at least one device is used for counting a number of arcing occurrences on the on the bare silicon substrate caused during the PVD process.

19. The system of claim 18, further comprising:
removing the bare silicon substrate from the testing environment;
adjusting at least one parameter associated with the PVD process;
loading another bare silicon substrate that has been pretreated with at least one of PBT or a film into the testing environment;
performing a PVD process on the another bare silicon substrate; and
counting a number of arcing occurrences on the another bare silicon substrate caused during the PVD process.

20. The system of claim 19, wherein the at least one parameter associated with PVD is at least one of:
a) DC power level provided to a target;
b) one of a substrate temperature or a substrate support temperature set point;
c) AC bias power level provided to the substrate support;
d) PVD chamber pressure;
e) one of a composition, pressure, or flow rate of backside gas;
f) one of a composition, pressure, or flow rate of top gas injection;
g) titanium (Ti) ignition; or
h) whether or not to use a degassing process, and if so, a temperature used during the degassing process.
